(19) United States
(12) Patent Application Publication
(10) Pub. No.: US 2013/0115745 A1
(43) Pub. Date: May 9, 2013

(54) METHODS OF MANUFACTURING SEMICONDUCTOR DEVICES INCLUDING DEVICE ISOLATION TRENCHES SELF-ALIGNED TO GATE TRENCHES

(71) Applicants: Hyun-woo Chung, Seoul (KR); Hyeong-sun Hong, Seongnam-si (KR); Yoo-sang Hwang, Suwon-si (KR); Ji-young Kim, Yongin-si (KR); Jay-bok Choi, Hwaseong-si (KR)

(72) Inventors: Hyun-woo Chung, Seoul (KR); Hyeong-sun Hong, Seongnam-si (KR); Yoo-sang Hwang, Suwon-si (KR); Ji-young Kim, Yongin-si (KR); Jay-bok Choi, Hwaseong-si (KR)

(21) Appl. No.: 13/607,315

(22) Filed: Sep. 7, 2012

(30) Foreign Application Priority Data
Nov. 7, 2011 (KR) 10-2011-0115364

(51) Int. Cl. H01L 21/336

(52) U.S. Cl. 438/270; 257/E21.41

(57) ABSTRACT

Methods of manufacturing a semiconductor device can be provided by forming a structure including a plurality of gate trenches that extend in a first direction and a mold layer having openings and that extend in the first direction on a substrate. Filling layers can be formed to fill the openings and the mold layer can be removed so that the filling layers remain on the substrate. A spacer layer can be formed which fills a space between the filling layers directly adjacent to each other at one side of each of the filling layers and forms a spacer at the sidewall of each of the filling layers at the other side of each of the filling layers. Device isolation trenches can be formed that extend in parallel to the plurality of gate trenches by etching the substrate exposed by the spacer layer.

### CROSS-REFERENCE TO RELATED APPLICATIONS

This application claims the benefit of Korean Patent Application No. 10-2011-0115364, filed on Nov. 7, 2011, in the Korean Intellectual Property Office, the disclosure of which is incorporated herein in its entirety by reference.

### BACKGROUND

1. Field of the Invention

The inventive concept relates to methods of manufacturing semiconductor devices, and more particularly, to methods of manufacturing a semiconductor device having a buried gate.

2. Description of the Related Art

With the development of the electronic industry and the increased demand of users, the integration densities and performance of electronic devices have improved. However, with the high integration densities of semiconductor devices, the sizes of transistors included in semiconductor devices have been reduced, thereby causing deterioration of electrical characteristics thereof. Thus, transistors having a buried gate have been developed.

### SUMMARY

Methods of manufacturing a semiconductor device can be provided by forming a structure including a plurality of gate trenches that extend in a first direction and a mold layer having openings and that extend in the first direction on a substrate. Filling layers can be formed to fill the openings and the mold layer can be removed so that the filling layers remain on the substrate. A spacer layer can be formed which fills a space between the filling layers directly adjacent to each other at one side of each of the filling layers and forms a spacer at the sidewall of each of the filling layers at the other side of each of the filling layers. Device isolation trenches can be formed that extend in parallel to the plurality of gate trenches by etching the substrate exposed by the spacer layer.

The openings may include a plurality of pairs of openings, wherein two openings of each of the plurality of pairs are apart from each other at a first interval in a second direction perpendicular to the first direction and the plurality of pairs are disposed at a second interval which is larger than the first interval.

The openings may be formed to fit vertically to the gate trenches in the substrate.

Each of the device isolation trenches may be respectively formed between every two gate trenches of the plurality of gate trenches in the second direction.

The forming of the structure may include: defining a plurality of active regions by forming a plurality of first device isolation regions having a form of a line extending in a third direction which is different from the first direction, in the substrate; forming a mold material layer for forming the mold layer on the substrate; forming the mold layer having the openings by etching the mold material layer; and forming the plurality of gate trenches which intersect with the plurality of the first device isolation regions and extend in the first direction, by etching the substrate exposed by the openings.

A length from the upper surface of the substrate to the lowest side of the device isolation trench may be smaller than a length from the upper surface of the substrate to the lowest side of the first device isolation region.

The first device isolation region may be divided in a form of an island by the device isolation trench.

The forming of the filling layers may include: forming in the plurality of gate trenches a gate line having a height which is lower than the upper surface of the substrate; and depositing a filling material in the plurality of gate trenches and the openings.

The method may further include forming a device isolation region by depositing an insulation material in the device isolation trenches.

A length from the upper surface of the substrate to the bottom of the device isolation trenches may be larger than a length from the upper surface of the substrate to the bottom of the plurality of gate trenches.

The method may further include: forming an insulation layer at an inside wall of the device isolation trench; and forming in the device isolation trenches a conductive layer having a height which is lower than the upper surface of the substrate.

The method may further include forming in the plurality of gate trenches a gate line having a height which is lower than the upper surface of the substrate, wherein the conductive layer is wired so that a voltage having a polarity opposite to that of the gate line is applied thereto.

The insulation layer and the conductive layer may be simultaneously formed in the plurality of gate trenches.

According to another aspect of the inventive concept, there is provided a method of manufacturing a semiconductor device, the method including: defining a plurality of active regions by forming a plurality of first device isolation regions extending in a first direction, in a substrate; forming a mask layer on the substrate; forming a plurality of holes in the mask layer and forming a plurality of gate trenches, which intersect with the plurality of first device isolation regions and extend in a second direction different from the first direction, in the substrate, by etching the mask layer and the substrate; forming in the plurality of gate trenches a gate line having a height which is lower than the upper surface of the substrate; forming a filling layer by forming a filling material in the plurality of gate trenches and the plurality of holes of the mask layer; removing the mask layer; forming a spacer at a sidewall of the filling layer; forming device isolation trenches by etching the substrate by using the spacer as a mask; and forming second device isolation regions by filling the device isolation trenches.

The plurality of gate trenches may include a plurality of pairs of gate trenches, two gate trenches of each of the plurality of pairs are adjacent to each other, and the spacer may be formed so that the upper surface of the substrate between the pair of gate trenches is not exposed.

### BRIEF DESCRIPTION OF THE DRAWINGS

Exemplary embodiments of the inventive concept will be more clearly understood from the following detailed description taken in conjunction with the accompanying drawings in which:

FIG. 1A is a layout diagram of a semiconductor device according to some embodiments of the inventive concept;

FIG. 1B is a cross-sectional view of the semiconductor device of FIG. 1A according to some embodiments of the inventive concept;

FIGS. 2A through 11B are diagrams according to process sequences to explain an exemplary methods of manufacturing the semiconductor device illustrated in FIGS. 1A and 1B;

FIG. 12A is a layout diagram of a semiconductor device according other embodiments of the inventive concept;

FIG. 12B is a cross-sectional view of the semiconductor device of FIG. 12A according to other embodiments of the inventive concept;

FIGS. 13A and 13B are cross-sectional views of semiconductor devices according to other embodiments of the inventive concept;

FIG. 14 is a cross-sectional view for explaining exemplary methods of manufacturing the semiconductor device illustrated in FIG. 13A or FIG. 13B; and

FIGS. 15 through 17 are cross-sectional views for explaining other exemplary methods of manufacturing the semiconductor device illustrated in FIG. 13A or FIG. 13B.

### DESCRIPTION OF THE EMBODIMENTS ACCORDING TO THE INVENTIVE CONCEPT

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

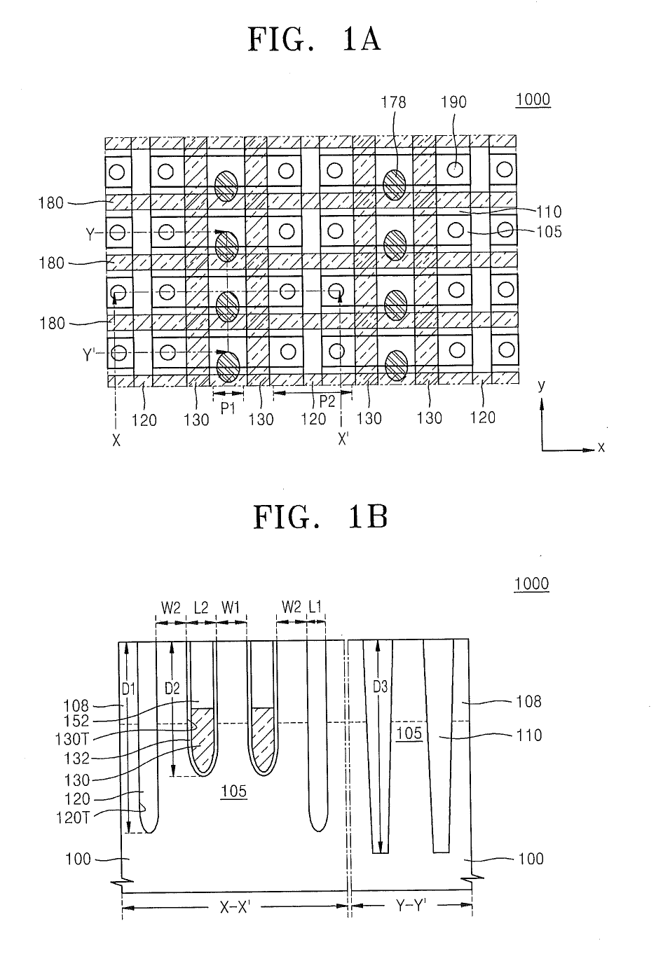

FIG. 1A is a layout diagram of a semiconductor device 1000 according to an embodiment of the inventive concept, and FIG. 1B is a cross-sectional view of the semiconductor device 1000 according to the embodiment of the inventive concept.

FIG. 1B illustrates a cross-sectional view taken along the lines X-X′ and Y-Y′ shown in FIG. 1A, and shows only some of elements of FIG. 1A. In FIG. 1B, a direct contact plug 178, a bitline 180, and a capacitor contact plug 190 of FIG. 1A are omitted.

The structure of the semiconductor device 1000 illustrated in FIGS. 1A and 1B may be also used, for example, for a cell array of a dynamic random access memory (DRAM). However, the inventive concept is not limited thereto.

Referring to FIGS. 1A and 1B, the semiconductor device 1000 includes a plurality of active regions 105 having an island shape, which are defined by first device isolation regions 110 and second device isolation regions 120 in a substrate 100. In addition, the semiconductor device 1000 includes a plurality of gate lines 130 intersecting with the plurality of active regions 105 and a plurality of bitlines 180 extending in a predetermined direction.

The substrate 100 may include, for example, a semiconductor, such as silicon or silicon-germanium. More specifically, the substrate 100 may include an epitaxial layer, a silicon on insulator (SIO) layer, or a semiconductor on insulator (SeOI) layer.

The active regions 105 may be formed in the shape of an island extending in a predetermined direction, for example, the X-axis direction in the substrate 100. The active regions 105 may be isolated from each other by the first device isolation regions 110 in the Y-axis direction, and may be isolated from each other by the second isolation regions 120 in the X-direction. Although in the current embodiment the active regions 105 are disposed to intersect the gate lines 130 at right angles, the inventive concept is not limited thereto, and the active regions 105 may be disposed to intersect with the gate lines 130 at an arbitrary angle.

The first device isolation regions 110 and the second device isolation regions 120 may be formed of an insulation material, for example, an oxide, a nitride, or a compound thereof The first device isolation regions 110 may be formed by using a shallow trench isolation (STI) process.

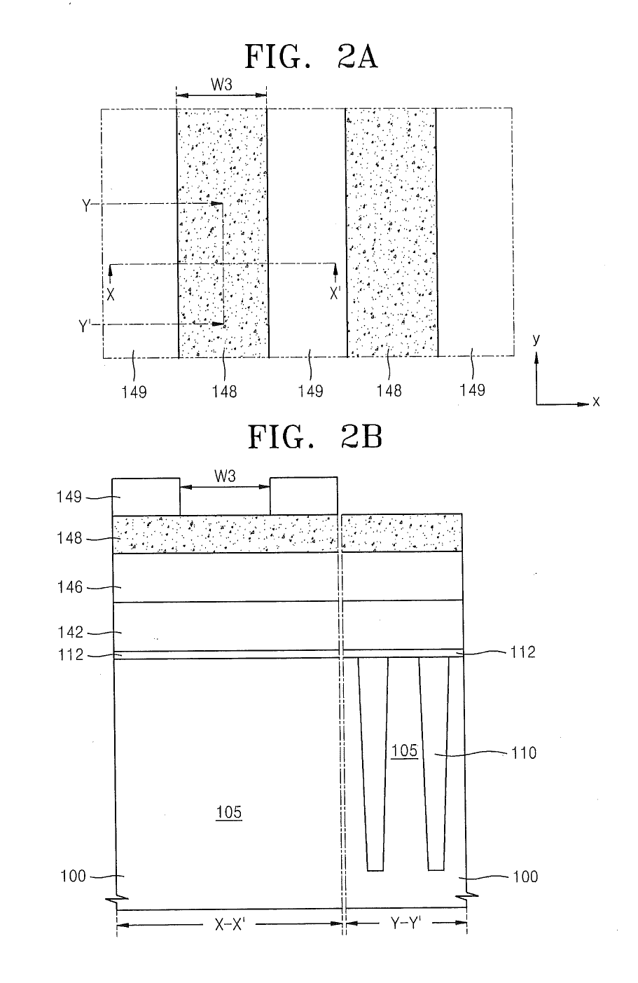

Each of the second device isolation regions 120 may be formed between every two gate lines 130 in the X-axis direction. The second device isolation region 120 may extend in a direction parallel with the gate lines 130. The second device isolation regions 120 may be disposed at one side of each of the gate lines 130, which is an opposite side of a side facing adjacent gate lines 130 so that the second device isolation region 120 is absent from between directly adjacent gate lines 130. The second device isolation regions 120 may be aligned by forming a device isolation trench 120T through a self-alignment at both sides of a pair of gate lines 130 disposed directly adjacent to each other. A method of forming the device isolation trench 120T will be explained in still greater detail with reference to FIGS. 2A and 11B below.

Each of the second device isolation regions 120 may have a first length L1 in the X-axis direction, and the first length L1 may be shorter than a second length L2 of a gate trench 130T in the x-axis direction. In addition, each of the second device isolation region 120 may have a first depth D1 from the upper surface of the substrate 100 to the lowest side of the second device isolation region 120, and the first depth D1 may be deeper than a second depth D2 from the upper surface the substrate 100 to the lowest side of the gate trench 130T. In addition, the first depth D1 may be shallower than a third depth D3 from the upper surface of the substrate 100 to the lowest side of the first device isolation region 110. However, the inventive concept is not limited to differences between relative depths, and the first through third depths D1-D3 may be variously changed.

The gate lines 130 may be disposed to extend in a direction crossing the active regions 105, for example, in the Y-axis direction in the substrate 100. The gate lines 130 may be buried wordlines constituting a buried channel array transistor (BCAT). As illustrated, a pair of directly adjacent gate lines 130 may be disposed to cross one active region 105. The pair of directly adjacent gate lines 130 crossing one active region 105 may extend apart from each other at a first interval P1. One of the pair of directly adjacent gate lines 130 may be apart from another pair of gate lines 130 at a second interval P2 which is larger than the first interval P1. A direction facing adjacent gate line 130 apart from one gate line 130 at the interval P1 is referred to as the inner direction of the gate line 130, and a direction facing adjacent gate line 130 apart from one gate line 130 at the interval P2 is referred to as the outer direction of the gate lines 130.

A gate insulation layer 132 may be formed at a sidewall of the gate trench 130T, and the gate lines 130 may be formed with a height (i.e., upper surface) lower than the upper surface of the substrate 100 on the gate insulation layer 132 (i.e., recessed within the trench 130T). The gate insulation layer 132 may be formed of an oxide, a nitride, or a compound thereof. In addition, the gate insulation layer 132 may include, for example, a silicon oxide or an insulation film having high permittivity. The gate lines 130 may be formed of a metal, a metal nitride, or a doped polysilicon. For example, the gate lines 130 may be formed of a titanium nitride (TiN). Upper surfaces of the gate lines 130 may be covered with a buried layer 152. The buried layer 152 may be formed of, for example, a silicon nitride.

A drain region may be formed between two directly adjacent gate lines 130 crossing one active region 105, and two source regions may be formed outside of the two directly adjacent gate lines. The source regions and the drain region are formed of an impurity region 108 by doping or ion implantation of substantially the same impurities, and may be reversely designated depending on a configuration of a circuit using transistors formed finally. A lower side boundary of the impurity region 108 may be lower than upper surfaces of the gate lines 130. The drain region may have a first width W1, and the source regions may have a second width W2 which is similar to the width W1.

The direct contact plug 178 may be formed on the drain region. The direct contact plug 178 electrically connects the drain region to the bitline 180. In the current embodiment, a drain voltage may be applied to transistors formed by directly adjacent gate lines 130, through one direct contact plug 178 formed in one active region 105. The capacitor contact plug 190 is formed on the source regions, and may electrically connect the source regions and a capacitor.

A plurality of bitlines 180 may extend in a predetermined direction, for example, the X-axis direction vertically to the plurality of gate lines 130. The plurality of bitlines 180 are disposed between the active regions in the Y-axis direction, thereby avoiding contact with the capacitor contact plug 190. The bitlines 180 may be formed on the substrate 100, or may be formed in the substrate 100 in the form of buried bitlines.

In the semiconductor device 1000, source regions may be formed to have equal widths to each other in one active region 105 by using the self-aligned second device isolation regions 120. Thus, uniformity of characteristics of transistors may be improved, and thus, reliability of the semiconductor device 100 may be improved too.

FIGS. 2A through 11B are diagrams illustrated according to process sequences to explain exemplary methods of manufacturing the semiconductor device illustrated in FIGS. 1A and 1B.

Referring to FIGS. 2A and 2B, FIG. 2A illustrates a plan view of an area corresponding to the layout of FIG. 1A, and FIG. 2B illustrates a cross-sectional view taken along the lines X-X′ and Y-Y′ shown in FIG. 2A.

The substrate 100 in which the active regions 105 are defined by the first device isolation region 110 is provided. A pad layer 112, a mold layer 142, a first mask layer 146, a second mask layer 148, and a mask pattern 149 (hereafter, referred to as a third mask pattern 149) of a third mask layer are sequentially formed on the substrate 100. For example, the pad layer 112, the mold layer 142, the first mask layer 146, and the second mask layer 148 may be formed by using chemical vapor deposition (CVD).

The pad layer 112 may protect the substrate 100, and for example, may be formed of a silicon oxide.

The mold layer 142 may be used to form a mask for forming the device isolation trench 120T (refer to FIG. 1B) in subsequent processes. The mold layer 142 may be formed of various films depending on a material of the substrate 100. For example, the mold layer 142 may be formed of a silicon compound material such as silicon oxide (SiO₂), silicon nitride (Si₃N₄), polysilicon, or the like.

The first mask layer 146 and the second mask layer 148 may be used to form the gate trench 130T having a narrow width (refer to FIG. 1B) by doubling a pattern density by using a double patterning process. The first mask layer 146, the second mask layer 148, and the mold layer 142 may be formed of materials having different etch selectivity, respectively. For example, the mold layer 142 may be formed of a silicon oxide, the first mask layer 146 may be formed of a silicon nitride, and the second mask layer 148 may be formed of a carbon compound film. For example, the carbon compound film may be a film including a carbon hydrogen compound or derivatives thereof, which has a relatively high carbon content of about 85% to about 99% on the basis of total weight, such as an amorphous carbon layer (ACL) or a spin-on hardmask (SOH).

The third mask pattern 149 may be formed in a form of a line extending in the Y-axis direction. By using the third mask pattern 149, a part corresponding to a third width W3 of the second mask layer 148 may be exposed. The third width W3 may correspond to a length from one end of a pair of gate trenches 130T crossing one active region 105 in FIG. 1B to the other end of the pair of gate trenches 130T. That is, the third width W3 may have a value (W1+L2×2) obtained by adding the first width W1 and a multiple of the second length L2. The third mask pattern 149 may be formed of the same material as the second mask layer 148. A reflection protection layer may be further formed on the third mask pattern 149 which is not illustrated.

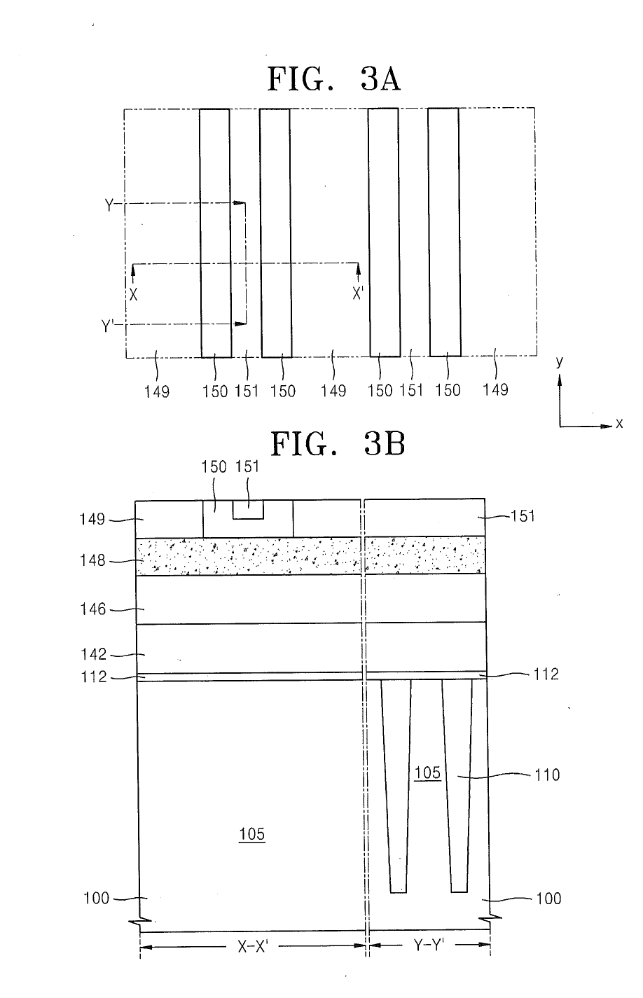

Referring to FIGS. 3A and 3B, FIG. 3A illustrates a plan view of an area corresponding to the layout of FIG. 1A, and FIG. 3B illustrates a cross-sectional view taken along the lines X-X′ and Y-Y′ shown in FIG. 3A.

A fourth mask layer 150 is stacked on the second mask layer 148 exposed by the third mask pattern 149. The fourth mask layer 150 may be formed to have a thickness smaller than that of the third mask pattern 149 so that a concave recess is formed at the center thereof. The fourth mask layer 150 may be formed of a material having a high etch selectivity to the second mask layer 148 and the third mask pattern 149. For example, if the second mask layer 148 and the third mask pattern 149 are formed of a nitride, the fourth mask layer 150 may formed of an oxide.

Next, a fifth mask layer 151 is formed to fill concave recess. After forming the fifth mask layer 151, excess material of the fourth mask layer 150 and a material of the fifth mask layer 151, on the third mask pattern 149, may be removed by using a planarization process. The fifth mask layer 151 may be formed of a material having a high etch selectivity to the fourth mask layer 150. In addition, the fifth mask layer 151 may be formed of the same material as the second mask layer 148 and the third mask pattern 149.

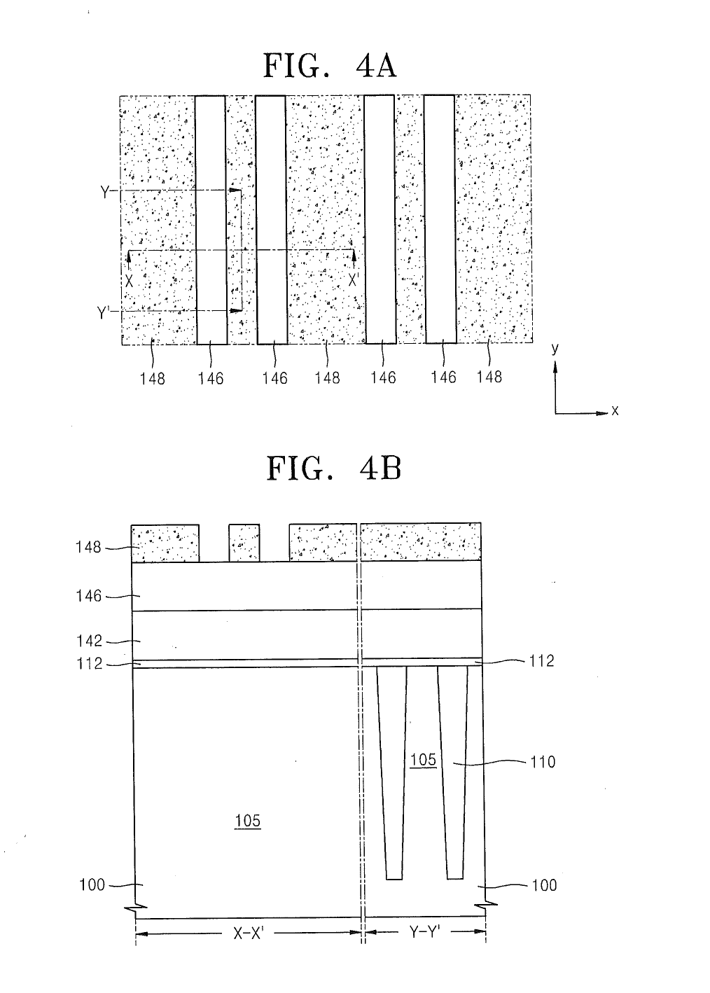

Referring to FIGS. 4A and 4B, FIG. 4A illustrates a plan view of an area corresponding to the layout of FIG. 1A, and FIG. 4B illustrates a cross-sectional view taken along the lines X-X′ and Y-Y′ shown in FIG. 4A.

An etching process is performed to selectively etch a part of the fourth mask layer 150 of FIG. 3B. The fourth mask layer 150 may be etched by using an anisotropic etching so that the second mask layer 148 is exposed. The etching process may use a dry etching or a reactive ion etching (RIE). After the etching process, the third mask pattern 149 and double layers including the other part of the fourth mask layer 150 and the fifth mask layer 151 remain on the second mask layer 148.

Next, the second mask layer 148 is etched by using the third mask pattern 149 and the double layers including the other part of the fourth mask layer 150 and the fifth mask layer 151. Thus, as illustrated in FIG. 4A, a part of the first mask layer 146 is exposed in a form of a line. The exposed first mask layer 146 may correspond to a location where the gate trenches 130T (refer to FIG. 1B) will be formed.

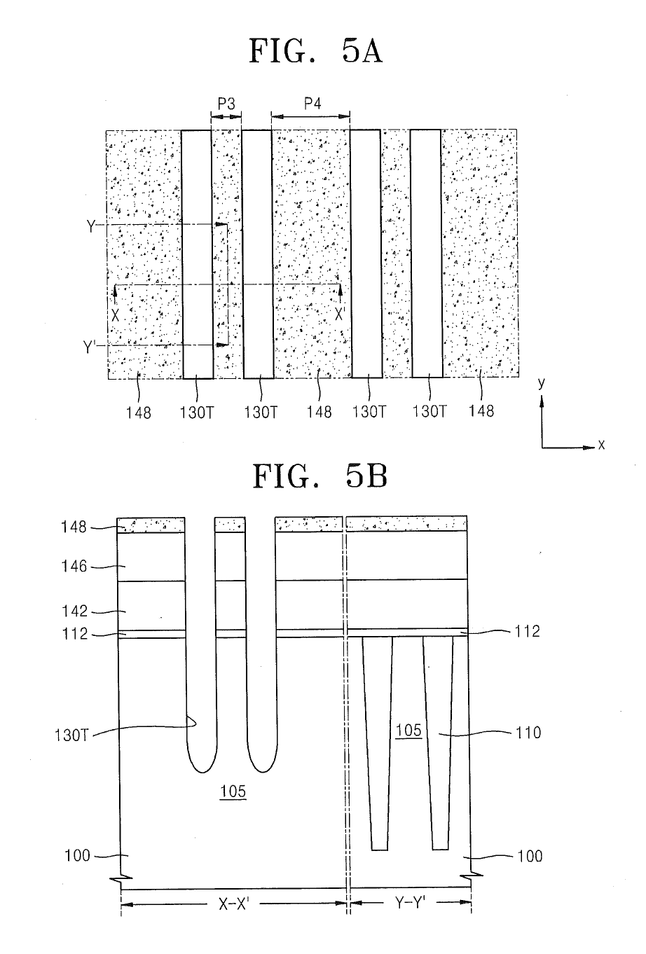

Referring to FIGS. 5A and 5B, FIG. 5A illustrates a plan view of an area corresponding to the layout of FIG. 1A, and FIG. 5B illustrates a cross-sectional view taken along the lines X-X′ and Y-Y′ shown in FIG. 5A.

The exposed first mask layer 146 and the mold layer 142, the pad layer 112, and the substrate 100 which are disposed below the exposed first mask layer 146 are sequentially removed to form the gate trenches 130T. The gate trenches 130T may be formed by using the anisotropic etching process, for example, a plasma etching process. During the removal, the height of the second mask layer 148 may be lowered due to etching.

Through this process, the gate trenches 130T extending in the Y-axis direction may be formed. The gate trenches 130T may be formed so that two kinds of pitches are alternately appeared between the gate trenches 130T in the X-axis direction. That is, the plurality of gate trenches 130T may be alternatively formed apart from each other at an interval P3 or an interval P4 which is larger than the interval P3.

In the current embodiment, a case where the gate trenches 130T are formed by using a double patterning process is explained, but the inventive concept is not limited thereto. The gate trenches 130T may be formed by using a mask patterned through a single photolithography process.

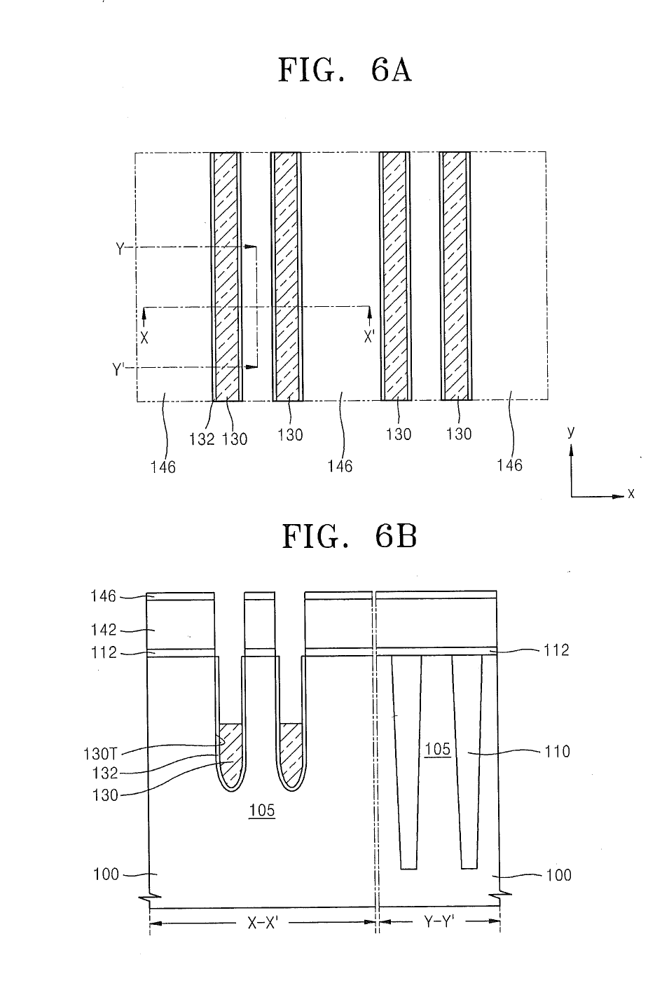

Referring to FIGS. 6A and 6B, FIG. 6A illustrates a plan view of an area corresponding to the layout of FIG. 1A, and FIG. 6B illustrates a cross-sectional view taken along the lines X-X′ and Y-Y′ shown in FIG. 6A.

First, the gate insulation layer 132 is formed on the inside wall of the gate trenches 130T. The gate insulation layer 132 may be formed by deposition of an insulation material and an etch-back process.

Next, the gate lines 130 are formed with a predetermined height inside the gate trenches 130T. The upper surface of the gate lines 130 may be lower than that of the substrate 100 (i.e., recessed within the gate trenches 130T). The gate lines 130 may be formed by deposition of a conductive material and an etch-back process.

The remaining second mask layer 148 of FIG. 5B may be removed during the etch-back process. The first mask layer 146 may be used as an etching stop layer during the etch-back process, and the height of the first mask layer 146 may be lowered by the etch-back process.

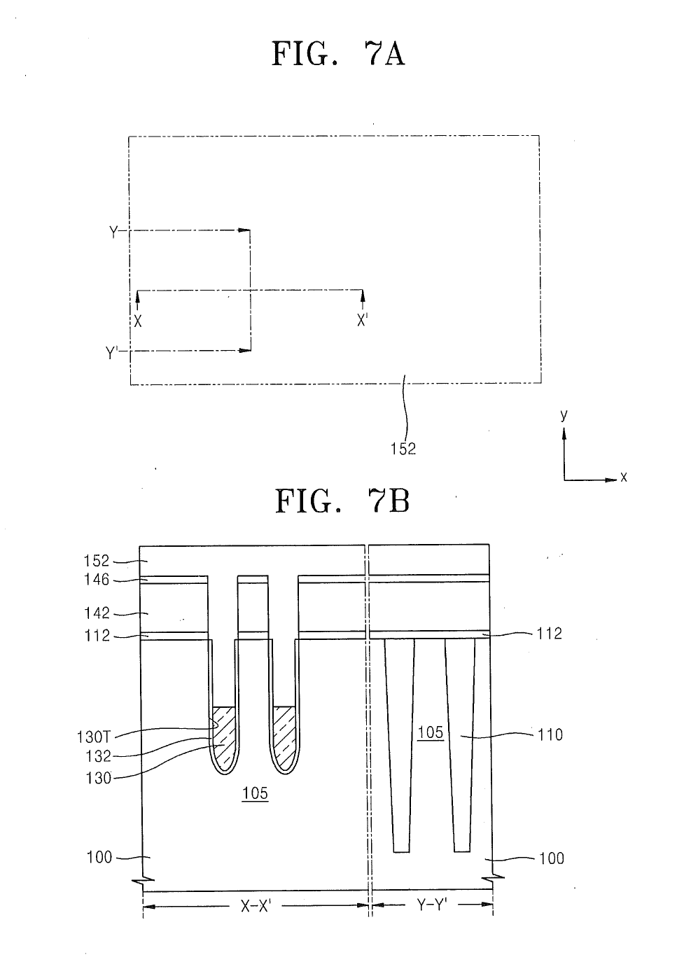

Referring to FIGS. 7A and 7B, FIG. 7A illustrates a plan view of an area corresponding to the layout of FIG. 1A, and FIG. 7B illustrates a cross-sectional view taken along the lines X-X′ and Y-Y′ shown in FIG. 7A.

A filling layer 152 may be formed to fill the gate trenches 130T on surfaces of the gate lines 130. The filling layer 152 may fill the insides of the gate trenches 130T and openings of the pad layer 112, mold layer 142, and first mask layer 146, and may be formed on the first mask layer 146.

The filling layer 152 may be formed of a material having a high etch selectivity relative to the mold layer 142. For example, if the mold layer 142 includes a silicon oxide, the filling layer 152 may include a silicon nitride.

Next, by performing a planarization process such as chemical mechanical polishing (CMP) or etch-back, the filling layer 152 and the remaining first mask layer 146, which are stacked on the mold layer 142, may be removed.

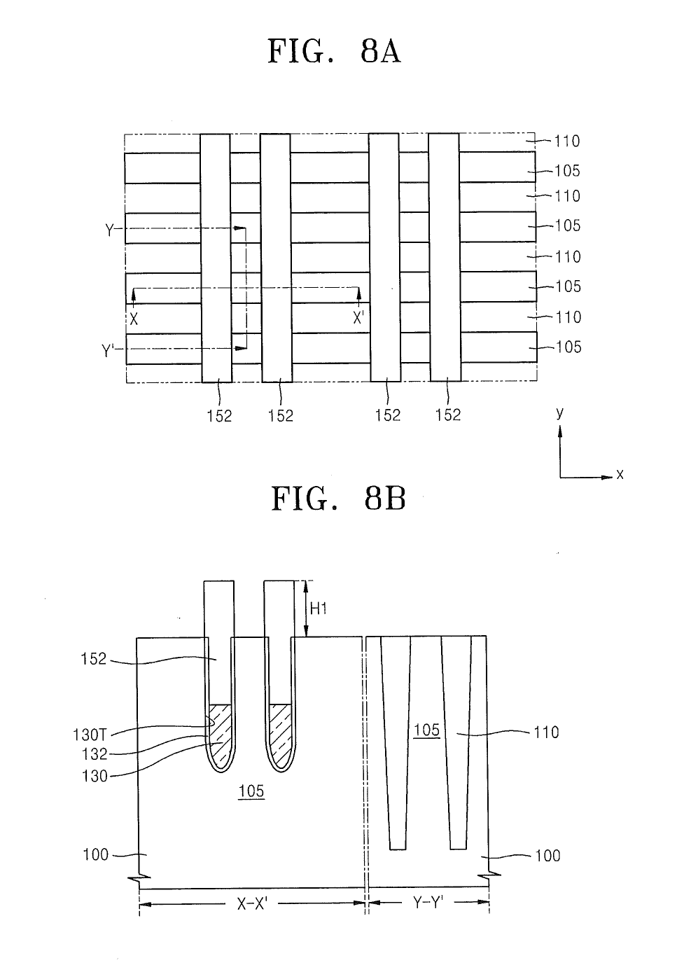

Referring to FIGS. 8A and 8B, FIG. 8A illustrates a plan view of an area corresponding to the layout of FIG. 1A, and FIG. 8B illustrates a cross-sectional view taken along the lines X-X′ and Y-Y′ shown in FIG. 8A.

The mold layer 142 and pad layer 112 of FIG. 7B may be selectively removed so that portions of the filling layer 152 protrude from the substrate 100. For example, the removal may be performed by using a wet etching. The removal may be performed in stages according to a material of the mold layer 142 and a material of the pad layer 112. In another embodiment according to the inventive concept, the pad layer 112 may not be removed, and may remain on the substrate 100.

The height H1 of the protruding portion of the filling layer 152 may depend in-part on the thickness of the mold layer 142, and may be higher than a predetermined height to form the device isolation trench 120T (refer to FIG. 1B) in a subsequent process.

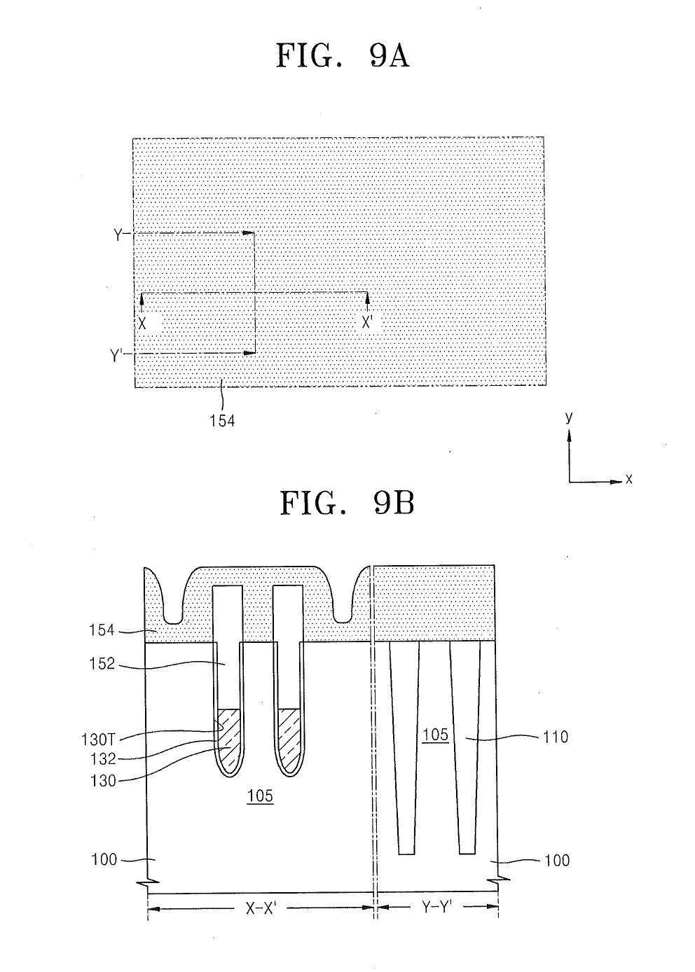

Referring to FIGS. 9A and 9B, FIG. 9A illustrates a plan view of an area corresponding to the layout of FIG. 1A, and FIG. 9B illustrates a cross-sectional view taken along the lines X-X′ and Y-Y′ shown in FIG. 9A.

A spacer material layer 154 is formed on the substrate 100 and the filling layer 152 to cover them. The spacer material layer 154 may be formed to have a thickness that allows filling of a space between directly adjacent protruding portions of the filling layer 152, which are formed on directly adjacent gate lines 130. In addition, the thickness of the spacer material layer 154 may be higher than a predetermined thickness so that the thickness of the spacer material layer 154 on the substrate 100 between the directly adjacent protruding portions of the filling layer 152 is higher than that of the spacer material layer 154 on the directly adjacent protruding portions of the filling layer 152.

The spacer material layer 154 may be formed of a material having a high etch selectivity to the substrate 100 and the first device isolation region 110. For example, the spacer material layer 154 may be formed of a silicon nitride.

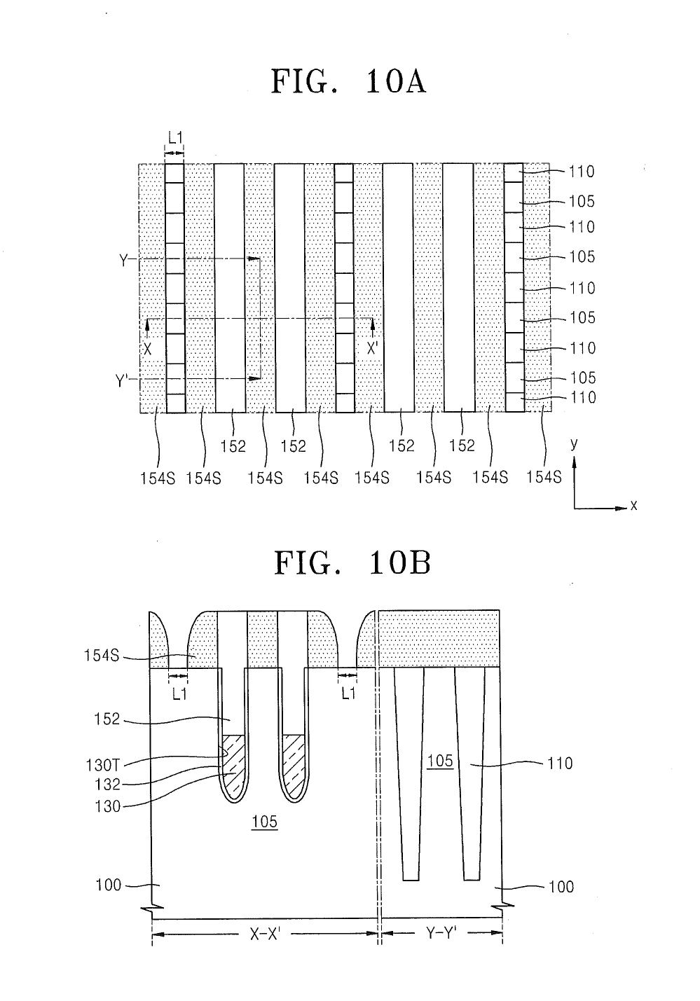

Referring to FIGS. 10A and 10B, FIG. 10A illustrates a plan view of an area corresponding to the layout of FIG. 1A, and FIG. 10B illustrates a cross-sectional view taken along the lines X-X′ and Y-Y′ shown in FIG. 10A.

A spacer layer 154S is formed by removing some of the spacer material layer 154. Some of the spacer material layer 154 may be removed by performing an etch-back process so that the upper surface of the filling layer 152 is exposed and the substrate 100 is exposed on surfaces adjacent to the directly adjacent protruding portions of the filling layer 152.

Accordingly, the spacer layer 154S fills a space between two directly adjacent protruding portions of the filling layer and the is on outer side walls of the two directly adjacent protruding portions, and forms a spacer on sidewall of each of the protruding portions of the filling layer 152 spaced apart from the directly adjacent protruding portions. That is, the spacer layer 154S only exposes a part of the substrate 100 corresponding to the first length L1 of the substrate 100 outside of the directly adjacent protruding portions of the filling layer 152. The first length L1 may correspond to a width of the device isolation trench 120T (refer to FIG. 1B).

In another embodiment, in a region between the adjacent filling layers 152, a center portion of the spacer layer 154S may be partially removed, and thus, the spacer layer 154S may have a concave form. In this case, the substrate 100 should not be exposed in the lower side of the region between the adjacent filling layers 152.

Referring to FIGS. 11A and 11B, FIG. 11A illustrates a plan view of an area corresponding to the layout of FIG. 1A, and FIG. 11B illustrates a cross-sectional view taken along the lines X-X′ and Y-Y′ shown in FIG. 11A.

The device isolation trenches 120T are formed by using the spacer layer 154S as a mask and etching exposed parts of the substrate 100. Since the device isolation trenches 120T are formed by using the spacer layer 154S, which is formed on the side walls of each of the filling layers 152, the device isolation trenches 120T may be formed apart from the gate trenches 130T by a predetermined interval. Thus, it is possible to prevent a misalignment which may occur during etching through a photolithography process. Thus, the source regions and drain region (on the both sides of the gate lines 130 explained above with reference to FIGS. 1A and 1B) may be uniformly formed to have a uniform size. In particular, the source regions which are formed outside of the pair of gate lines 130 may be formed to have a uniform size.

In the current embodiment, the device isolation trenches 120T have a depth which is deeper than that of the gate trenches 130T and shallower than that of the first device isolation region 110. However, the inventive concept is not limited thereto, and relative depths of the device isolation trenches 120T and first device isolation region 110 may be changed.

During the etching process, the height of the spacer layer 154S and filling layer 152 may be lowered due to etching. Thus, the thickness of the filling layers 152, which is determined during a previous process, may be determined according to a remaining thickness, in consideration of a thickness which is removed during the current etching process. In addition, since the thickness of the filling layers 152 is determined by the mold layer 142, consequently, the thickness of the filling layers 152 may be considered when determining the thickness of the mold layer 142 in the process explained above with reference to FIGS. 2A and 2B.

Next, referring to FIG. 1B as well as FIGS. 11A and 11B, the second device isolation region 120 may be formed by depositing an insulation material inside the device isolation trenches 120T. Thus, the active regions 105 having a line shape are divided in the X-axis direction, and thus, the active regions 105 have the shape of an island. Next, a drain region is formed in an active region between the two gate lines 130, and the impurity region 108 may be formed by implanting impurities to form a source region in an active region of the outside of the two gate lines 130. The impurity region 108 may include N-type or P- type impurities. The concentration of the impurities may be adjusted in consideration of characteristics of a semiconductor device which is formed finally. The energy for implanting the impurities may be selected so that a lower boundary of the impurity region 108 is lower than an upper surface of the gate lines 130.

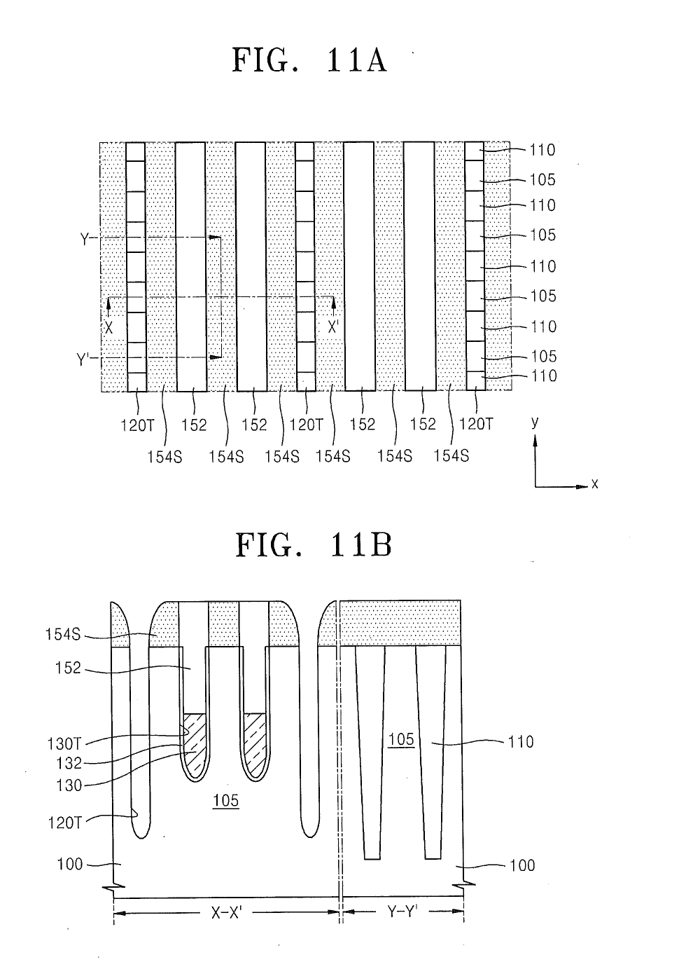

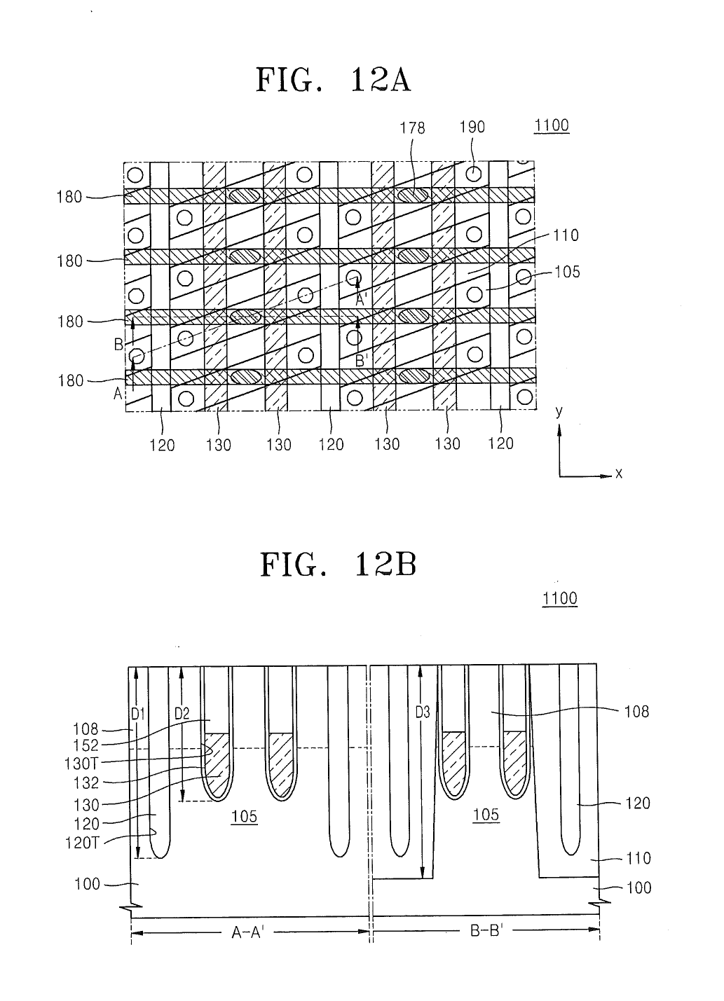

FIG. 12A is a layout diagram of a semiconductor device 1100 according to another embodiment of the inventive concept, and FIG. 12B is a cross-sectional view of the semiconductor device 1100 according to another embodiment of the inventive concept.

FIG. 12B illustrates a cross-sectional view taken along the lines X-X′ and Y-Y′ shown in FIG. 12A, and shows only some of elements of FIG. 12A. In FIG. 12B, a direct contact plug 178, a bitline 180, and a capacitor contact plug 190 of FIG. 1A are omitted. Like reference numerals and like symbols in FIGS. 12A and 12B and FIGS. 1A and 1B refer to like elements throughout, and thus, overlapping explanations will be omitted.

Referring to FIGS. 12A and 12B, the semiconductor device 1100 includes a plurality of active regions 105 having an island shape, which are defined by first device isolation regions 110 and second device isolation regions 120 in a substrate 100. In addition, the semiconductor device 1100 includes a plurality of gate lines 130 intersecting with the plurality of active regions 105 and a plurality of bitlines 180.

The active regions 105 may intersect with the gate lines 130 inside the substrate 100, and may be disposed in the shape of a rectangle extending in an oblique direction, for example, a direction between the X-axis direction and the Y-axis direction. The active regions 105 may be isolated from each other by the first device isolation regions 110 in the Y-axis direction, and may be isolated from each other by the second isolation regions 120 in the direction between the X-axis direction and the Y-axis direction.

A plurality of bitlines 180 may extend in a predetermined direction, for example, the X-axis direction, vertically to the plurality of gate lines 130. The plurality of bitlines 180 are disposed to intersect with parts of the active regions 105 in the Y-axis direction, thereby being prevented to contact the capacitor contact plug 190.

Each of the second device isolation regions 120 may be respectively disposed between every two gate lines 130 in the X-axis direction. The second device isolation regions 120 may extend in a direction parallel with the gate lines 130. The second device isolation regions 120 may be aligned by forming a device isolation trench 120T through a self-alignment outside a pair of gate lines 130 disposed adjacent to each other.

The second device isolation regions 120 may have a first depth D1 from the upper surface of the substrate 100 to the lowest side of the second device isolation region 120, and the first depth D1 may be deeper than a second depth D2 from the upper surface the substrate 100 to the lowest side of the gate trench 130T. In addition, the first depth D1 may be shallower than a third depth D3 from the upper surface of the substrate 100 to the lowest side of the first device isolation region 110.

In the semiconductor device 1100, the second device isolation regions 120 self- aligned with the gate lines 130 may be disposed regardless of an angle between the active regions 105 and the gate lines 130.

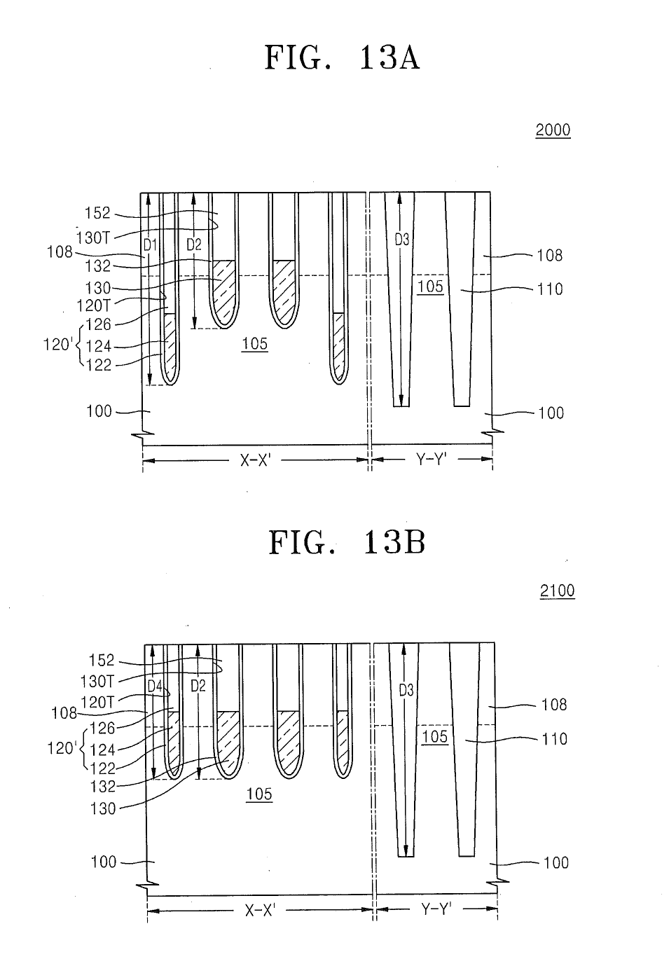

FIGS. 13A and 13B are cross-sectional views of semiconductor devices 2000 and 2100 according to other embodiments of the inventive concept. FIGS. 13A and 13B illustrate cross-sectional views corresponding to the cross-sectional view taken along the lines X-X′ and Y-Y′ shown in FIG. 1A. Like reference numerals and like symbols in FIGS. 13A and 13B and FIG. 1B refer to like elements throughout, and thus, overlapping explanations will be omitted.

Referring to FIGS. 13A and 13B, the semiconductor device 2000 or 2100 includes a plurality of active regions 105 having an island shape, which are defined by first device isolation regions 110 and second device isolation regions 120′ in a substrate 100. In addition, the semiconductor device 2000 or 2100 includes a plurality of gate lines 130 intersecting with the plurality of active regions 105.

Each of the second device isolation regions 120′ may be respectively disposed between every two gate lines 130 in the X-axis direction. The second device isolation region 120′ may extend in a direction parallel to the gate lines 130. The second device isolation regions 120′ may be aligned by forming a device isolation trench 120T through a self-alignment in the outside of a pair of gate lines 130 disposed adjacent to each other.

The second device isolation regions 120′ include an insulation layer 122 formed on the sidewall of the device isolation trench 120T, a conductive layer 124 formed on the insulation layer 122 with a height which is lower than the upper surface of the substrate 100, and a capping layer 126 formed on the conductive layer 124. The insulation layer 122 may be formed of an oxide, a nitride, or a compound thereof. In addition, the insulation layer 122 may include, for example, a silicon oxide or an insulation film having high permittivity. The conductive layer 124 may be formed of a metal, a metal nitride, or a doped polysilicon. For example, the conductive layer 124 may be formed of a titanium nitride (TiN). An upper side of the conductive layer 124 may be covered with the capping layer 126. The capping layer 126 may be formed of, for example, a silicon nitride.

When a transistor including a gate line 130 operates, a depletion region is formed in an active region 105 of the circumference of the gate line 130. In this case, the conductive layer 124 of the second device isolation regions 120′ may be wired so that a voltage having a polarity different from that of the gate line 130 may be applied thereto. Thus, by using this second device isolation regions 120′, the gate line 130 may be electrically cut off from another adjacent gate line 130. Although the second device isolation regions 120′ are formed to have a similar structure to the inside of a gate trench 130T, the second device isolation regions 120′ may have a device isolation function.

In the semiconductor device 2000 of FIG. 13A, the second device isolation region 120′ may have a first depth D1 from the upper surface of the substrate 100 to the lowest side of the second device isolation region 120′, and the first depth D1 may be deeper than a second depth D2 from the upper surface the substrate 100 to the lowest side of the gate trench 130T. In addition, the first depth D1 may be shallower than a third depth D3 from the upper surface of the substrate 100 to the lowest side of the first device isolation region 110.

In the semiconductor device 2100 of FIG. 13B, the second device isolation region 120′ may have a fourth depth D4 from the upper surface of the substrate 100 to the lowest side of the second device isolation regions 120′, and the first depth D4 may be equal to a second depth D2 from the upper surface the substrate 100 to the lowest side of the gate trench 130T. In addition, the fourth depth D4 may be shallower than the third depth D3 from the upper surface of the substrate 100 to the lowest side of the first device isolation region 110.

FIG. 14 is a cross-sectional view for explaining an exemplary method of manufacturing the semiconductor device illustrated in FIG. 13A or FIG. 13B. FIG. 14 illustrates a cross-sectional view corresponding to the cross-sectional view taken along the lines X-X′ and Y-Y′ shown in FIG. 1A.

Referring to FIG. 14, first, a process of forming the device isolation trench 120T may be performed in the same manner as explained above with reference to FIGS. 2A through 11B.

Next, an insulation layer 122 is formed at the inside wall of a device isolation trench 120T. The insulation layer 122 may be formed by deposition of an insulation material and an etch-back process. Next, a conductive layer 124 is formed with a predetermined height inside the device isolation trench 120T. The upper surface of the conductive layer 124 may be lower than that of the substrate 100. The conductive layer 124 may be formed by deposition of a conductive material and an etch-back process.

Next, a capping layer 126 is formed on the conductive layer 124, and the semiconductor device 2000 of FIG. 13A or the semiconductor device 2100 of FIG. 13B may be formed by performing a planarization process and an impurity injection process.

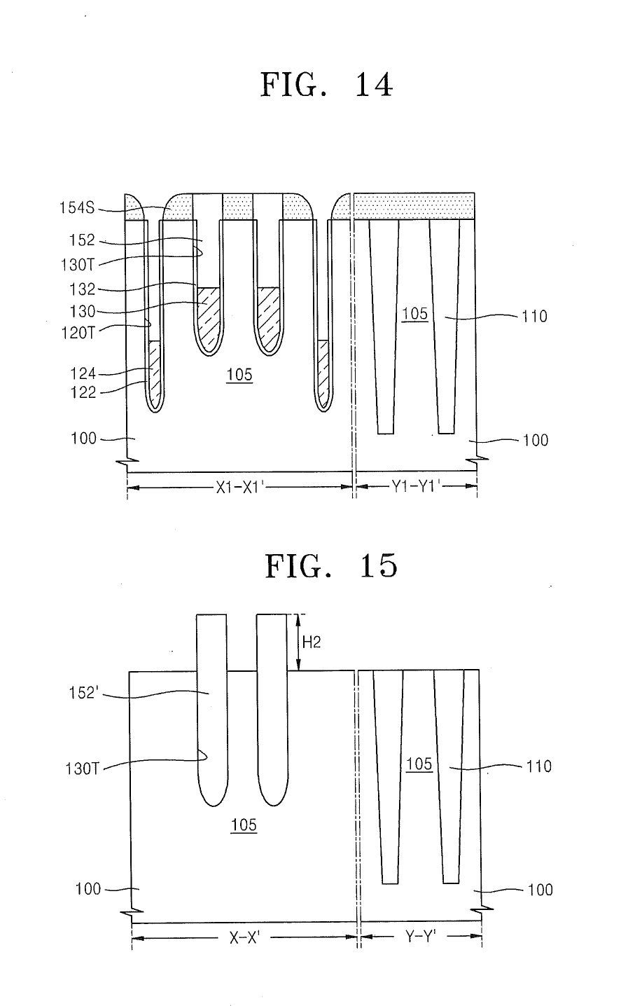

FIGS. 15 through 17 are cross-sectional views for explaining another exemplary method of manufacturing the semiconductor device illustrated in FIG. 13A or FIG. 13B. FIGS. 15 through 17 illustrate cross-sectional views corresponding to the cross-sectional view taken along the lines X-X′ and Y-Y′ shown in FIG. 1A.

Referring to FIG. 15, first, a process of forming the gate trenches 130T may be performed in the same manner as explained above with reference to FIGS. 2A through 5B. However, the first mask layer 146 of FIGS. 2A through 5B may be omitted. Next, a filling layer 152′ for filling the gate trenches 130T is formed in a similar manner to the process stated above with reference to FIGS. 7A and 7B. However, in the current embodiment, the filling layer 152′ is formed from the bottom surface of the gate trenches.

Next, the mold layer 142 and the pad layer 112 of FIG. 7B may be selectively removed to so that a portion of the filling layer 152′ protrudes from the substrate 100. The filling layer 152′ is formed to be projected with a predetermined projection height H2 on the substrate 100.

Referring to FIG. 16, a process of forming the spacer layer 154S may be performed in the same manner as explained above with reference to FIGS. 9A through 10B. Next, a process of forming the device isolation trench 120T as stated above with reference to FIGS. 11A and 11B may be performed in the same manner.

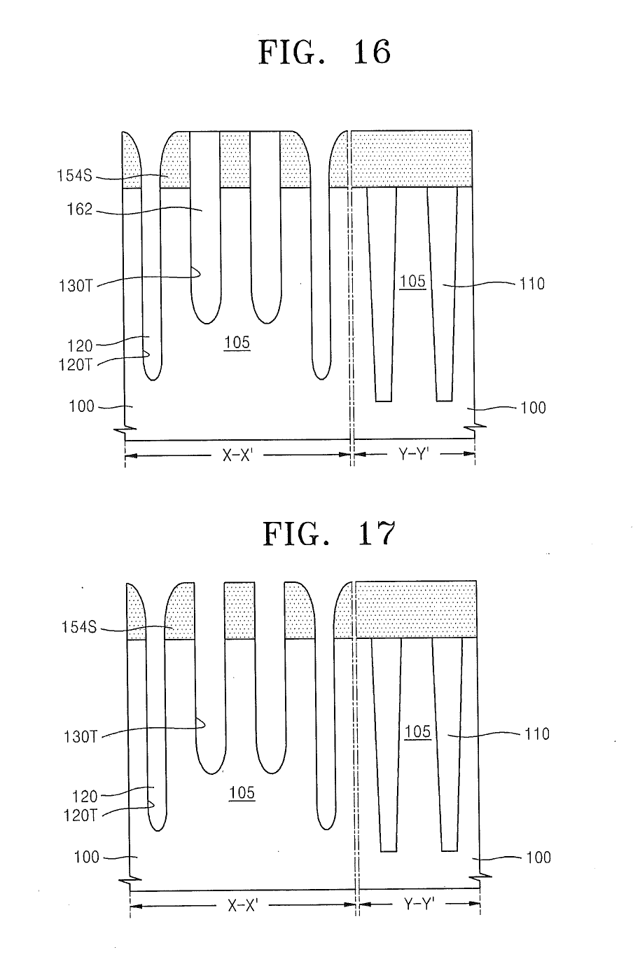

Referring to FIG. 17, the filling layer 152′ filled in the gate trenches 130T is selectively removed. For example, the removal is performed by using a wet etching.

Next, referring to FIGS. 13A and 13B, it is possible to simultaneously form the insulation layer 122 and the gate insulation layer 132 in the device isolation trench 120T and the gate trench 130T, respectively. In addition, it is possible to simultaneously form the conductive layer 124 and the gate line 130 in the device isolation trench 120T and the gate trench 130T, respectively.

According to the embodiments of the inventive concept, processes of manufacturing the semiconductor device may be simplified since a process of filling the device isolation trench 120T and a process of filling the gate trench 130T are simultaneously performed.

While the inventive concept has been particularly shown and described with reference to exemplary embodiments thereof, it will be understood that various changes in form and details may be made therein without departing from the spirit and scope of the inventive concept as defined by the following claims.

What is claimed is:

1. A method of manufacturing a semiconductor device, the method comprising:
forming a structure comprising a plurality of gate trenches extending in a first direction and a mold layer having openings extending in the first direction on a substrate;
forming filling layers to fill the openings;
removing the mold layer so that the filling layers remain on the substrate;
forming a spacer layer which fills a space between the filling layers directly adjacent to each other at one side of each of the filling layers and forms a spacer at the sidewall of each of the filling layers at the other side of each of the filling layers; and
forming device isolation trenches extending in parallel to the plurality of gate trenches by etching the substrate exposed by the spacer layer.

2. The method of claim 1, wherein the openings comprise a plurality of pairs of openings, wherein two openings of each of the plurality of pairs are apart from each other at a first interval in a second direction perpendicular to the first direction and the plurality of pairs are disposed at a second interval which is larger than the first interval.

3. The method of claim 1, wherein the openings are formed to fit vertically to the gate trenches in the substrate.

4. The method of claim 1, wherein each of the device isolation trenches is respectively formed between every two gate trenches of the plurality of gate trenches in the second direction.

5. The method of claim 1, wherein the forming of the structure comprises:
defining a plurality of active regions by forming a plurality of first device isolation regions having a form of a line extending in a third direction which is different from the first direction, in the substrate;
forming a mold material layer for forming the mold layer on the substrate;
forming the mold layer having the openings by etching the mold material layer; and
forming the plurality of gate trenches which intersect with the plurality of the first device isolation regions and extend in the first direction, by etching the substrate exposed by the openings.

6. The method of claim 5, wherein a length from an upper surface of the substrate to a bottom of the device isolation trench is smaller than a length from the upper surface of the substrate to a bottom of the first device isolation region.

7. The method of claim 5, wherein the first device isolation region is divided in a form of an island by the device isolation trenches.

8. The method of claim 1, wherein the forming of the filling layers comprise:
forming in the plurality of gate trenches, a gate line having a height which is lower than an upper surface of the substrate; and
depositing a filling material in the plurality of gate trenches and the openings.

9. The method of claim 1, further comprising forming device isolation regions by depositing an insulation material in the device isolation trenches.

10. The method of claim 1, wherein a length from an upper surface of the substrate to a bottom of the device isolation trench is larger than a length from the upper surface of the substrate to a bottom of the plurality of gate trenches.

11. The method of claim 1, further comprising:
forming an insulation layer on an inside wall of the device isolation trenches; and
forming in the device isolation trenches, a conductive layer having a height which is lower than an upper surface of the substrate.

12. The method of claim 11, further comprising forming in the plurality of gate trenches a gate line having a height which is lower than the upper surface of the substrate,
wherein the conductive layer is wired so that a voltage having a polarity opposite to that of the gate line is applied thereto.

13. The method of claim 11, wherein the insulation layer and the conductive layer are simultaneously formed in the plurality of gate trenches.

14. A method of manufacturing a semiconductor device, the method comprising:
defining a plurality of active regions by forming a plurality of first device isolation regions extending in a first direction, in a substrate;
forming a mask layer on the substrate;
forming a plurality of holes in the mask layer and forming a plurality of gate trenches, which intersect with the plurality of first device isolation regions and extend in a second direction different from the first direction, in the substrate, by etching the mask layer and the substrate;
forming in the plurality of gate trenches, a gate line having a height which is lower than an upper surface of the substrate;
forming a filling layer by forming a filling material in the plurality of gate trenches and the plurality of holes of the mask layer;
removing the mask layer;
forming a spacer at a sidewall of the filling layer;
forming device isolation trenches by etching the substrate by using the spacer as a mask; and
forming second device isolation regions by filling the device isolation trenches.

15. The method of claim 14, wherein the plurality of gate trenches comprise a plurality of pairs of gate trenches, two gate trenches of each of the plurality of pairs are directly adjacent to each other, and the spacer is formed so that the upper surface of the substrate between the pair of gate trenches is not exposed.

16. A method of forming a semiconductor device comprising:
forming gate trenches comprising a first width, the gate trenches extending along a first direction in a substrate; and
forming device isolation trenches comprising a second width, that is less than the first width, the device isolation trenches extending along the first direction self-aligned to the gate trenches.

17. The method of claim 16 wherein device isolation trenches extend in the first direction parallel to the gate trenches.

18. The method of claim 16 wherein forming gate trenches further comprises:
forming a filling layer in the gate trenches to provide protruding portions of the filling layer that protrude from the gates trenches above the substrate; and
forming spacers on the protruding portions that are directly adjacent to one another on the substrate, including on outer side walls thereof.

19. The method of claim 18 wherein forming device isolation trenches comprising a second width, that is less than the first width, the device isolation trenches extending along the first direction self-aligned to the gate trenches, comprising etching the substrate to form the device isolation trenches self-aligned to the gate trenches.

20. The method of claim 19 further comprising:
forming an insulating material on the substrate and in the device isolation trenches to provide device isolation layers in the substrate.

21. The method of claim 16 wherein bottoms of the device isolation trenches are deeper in the substrate than bottoms of the gate trenches.

22. The method of claim 16 wherein forming gate trenches further comprises:
forming a conductive layer in the gate trenches at the bottom thereof and extending toward an opening thereof to provide an upper surface that is beneath a surface of the substrate; and
forming a buried layer on the upper surface.

23. The method of claim 22 wherein the conductive layer comprises a first conductive layer and the buried layer comprises a first buried layer, wherein forming device isolation trenches further comprises:
forming a second conductive layer in the device isolation trenches at a bottom thereof and extending toward an opening thereof to provide an upper surface that is beneath the surface of the substrate; and
forming a second buried layer on the upper surface.

24. The method of claim 23 wherein the first and second conductive layers are formed simultaneously.

25. The method of claim 23 wherein the bottom of the device isolation trenches is deeper than the bottom of the gate trenches.

26. The method of claim 23 wherein the bottom of the device isolation trenches and the bottom of the gate trenches are at about equal depths.
